(19) United States
(12) Patent Application Publication
(10) Pub. No.: US 2007/0052465 A1
(43) Pub. Date: Mar. 8, 2007

(54) SCHMITT TRIGGER WITH ELECTROSTATIC DISCHARGE (ESD) PROTECTION

(76) Inventor: Ho-Chun Wu, I-Lan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/470,257

(22) Filed: Sep. 6, 2006

(30) Foreign Application Priority Data
Sep. 8, 2005 (TW) 094130911

(51) Int. Cl. H03K 3/00

(52) U.S. Cl. 327/206

(57) ABSTRACT

An Schmitt trigger with electrostatic discharge protection includes a first PMOS, a second PMOS, a first NMOS, and a second NMOS, which are connected in series and each of which has a gate coupled to an input terminal. The drain of the second PMOS is coupled to an output terminal. The source of the first PMOS is coupled to a first voltage. The source of the second NMOS is coupled to a second voltage. The Schmitt trigger further includes a third PMOS, which has a gate coupled to the output terminal, a source coupled to the drain of the first PMOS, and a drain coupled to the second voltage through a poly-silicon resistor; and a third NMOS which has a gate coupled to the output terminal, a source coupled to the source of the first NMOS, and a drain coupled to the first voltage through a poly-silicon resistor.

### BACKGROUND OF THE INVENTION

1. Field of the Invention

The present disclosure relates to Schmitt triggers, and more particularly, to Schmitt triggers with electrostatic discharge (ESD) protection.

2. Description of the Prior Art

Electrostatic discharge (ESD) usually causes electronic devices or electronic system to be damaged by electrical overstress (EOS), which results in permanent damage to semiconductor devices thereby adversely affecting the performance of integrated circuits. Typically, the ESD damage often occurs in the Schmitt trigger inside the integrated circuits. A conventional approach to solve this problem is disclosed in the Taiwan Patent Application No.00333693.

### SUMMARY OF THE INVENTION

It is therefore an objective of the present disclosure to provide Schmitt triggers with electrostatic discharge (ESD) protection to increase the circuit reliability.

An exemplary embodiment of an Schmitt trigger with electrostatic discharge protection is disclosed comprising: a first PMOS transistor having a gate coupled to an input terminal of the Schmitt trigger, a source coupled to a first voltage, and a drain; a second PMOS transistor having a gate coupled to the input terminal of the Schmitt trigger, a source coupled to the drain of the first PMOS transistor, and a drain coupled to an output terminal of the Schmitt trigger; a first NMOS transistor having a gate coupled to the input terminal of the Schmitt trigger, a drain coupled to the drain of the second PMOS transistor, and a source; a second NMOS transistor having a gate coupled to the input terminal of the Schmitt trigger, a drain coupled to the source of the first NMOS transistor, and a source coupled to a second voltage; a third PMOS transistor having a gate coupled to the output terminal of the Schmitt trigger, a source coupled to the drain of the first PMOS transistor, and a drain coupled to the second voltage through a poly-silicon resistor; and a third NMOS transistor having a gate coupled to the output terminal of the Schmitt trigger, a source coupled to the source of the first NMOS transistor, and a drain coupled to the first voltage through a poly-silicon resistor.

An exemplary embodiment of another Schmitt trigger with electrostatic discharge protection is disclosed comprising: a plurality of cascaded transistors, a third transistor, and a fourth transistor. The plurality of cascaded transistors comprises a first transistor having a gate coupled to an input terminal of the Schmitt trigger, and a source coupled to a first voltage; and a second transistor having a gate coupled to the input terminal of the Schmitt trigger, and a source coupled to a second voltage. The third transistor has a source coupled to a drain of the first transistor, and a drain coupled to the second voltage through a first poly-silicon resistor. The fourth transistor has a source coupled to a drain of the second transistor, and a drain coupled to the first voltage through a second poly-silicon resistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an Schmitt trigger according to an exemplary embodiment of the present invention.

### DETAILED DESCRIPTION

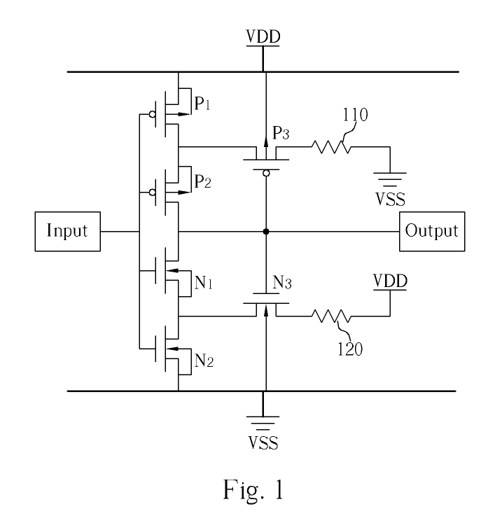

Please refer to FIG. 1, which shows a schematic diagram of an Schmitt trigger according to an exemplary embodiment of the present invention. As illustrated, the Schmitt trigger comprises: a first PMOS transistor having a gate coupled to an input terminal of the Schmitt trigger, a source coupled to a VDD voltage, and a drain; a second PMOS transistor having a gate coupled to the input terminal of the Schmitt trigger, a source coupled to the drain of the first PMOS transistor, and a drain coupled to an output terminal of the Schmitt trigger; a first NMOS transistor having a gate coupled to the input terminal of the Schmitt trigger, a drain coupled to the drain of the second PMOS transistor, and a source; a second NMOS transistor having a gate coupled to the input terminal of the Schmitt trigger, a drain coupled to the source of the first NMOS transistor, and a source coupled to a VSS voltage; a third PMOS transistor having a gate coupled to the output terminal of the Schmitt trigger, a source coupled to the drain of the first PMOS transistor, and a drain coupled to the VSS voltage through a first resistor 110; and a third NMOS transistor having a gate coupled to the output terminal of the Schmitt trigger, a source coupled to the source of the first NMOS transistor, and a drain coupled to the VDD voltage through a second resistor 1 20.

There are many approaches can be adopted to form a resistor in an integrated circuit, such as metal resistance, diffusion resistance, well resistance, poly resistance, etc., and these resistances belong to passive device. Generally, to form a resistor by adopting poly resistance in the integrated circuit is easier and more convenient. A poly-silicon resistor occupies a relative smaller area in the layout and can be implemented without using complex circuitry, thereby reducing the required time for layout. Since the poly-silicon resistor has an ideal resistance property, the load 110 and the load 120 of the FIG. 1 can both be implemented with poly-silicon resistors to solve the ESD problem of the Schmitt trigger.

In addition, the Schmitt trigger of this embodiment is manufactured by 0.35-μm process or a more advanced process, such as 0.25/0.18/0.13/0.09-μm process. Moreover, since the load 110 and the load 120 are implemented with poly-silicon resistors, the Schmitt trigger can be protected from being damaged by the ESD caused by the improper layout. For example, if the poly-silicon resistor 120 of FIG. 1 is removed, the third NMOS transistor's bulk (which is coupled to the VSS voltage) and the third NMOS transistor's drain (which is coupled to the VDD voltage) are easily conducted due to the high voltage difference. This adversely affects the ESD protection performance. Similarly, if the poly-silicon resistor 110 of FIG. 1 is removed, the third PMOS transistor's bulk (which is coupled to the VDD voltage) and the third PMOS transistor's drain (which is coupled to the VSS voltage) are easily conducted due to the high voltage difference, thereby adversely affecting the ESD protection performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An Schmitt trigger with electrostatic discharge protection comprising:
a first PMOS transistor having a gate coupled to an input terminal of the Schmitt trigger, a source coupled to a first voltage, and a drain;
a second PMOS transistor having a gate coupled to the input terminal of the Schmitt trigger, a source coupled to the drain of the first PMOS transistor, and a drain coupled to an output terminal of the Schmitt trigger;
a first NMOS transistor having a gate coupled to the input terminal of the Schmitt trigger, a drain coupled to the drain of the second PMOS transistor, and a source;
a second NMOS transistor having a gate coupled to the input terminal of the Schmitt trigger, a drain coupled to the source of the first NMOS transistor, and a source coupled to a second voltage;
a third PMOS transistor having a gate coupled to the output terminal of the Schmitt trigger, a source coupled to the drain of the first PMOS transistor, and a drain coupled to the second voltage through a poly-silicon resistor; and
a third NMOS transistor having a gate coupled to the output terminal of the Schmitt trigger, a source coupled to the source of the first NMOS transistor, and a drain coupled to the first voltage through a poly-silicon resistor.

2. The Schmitt trigger of claim 1 is manufactured by 0.35-μm process or a more advanced process.

3. The Schmitt trigger of claim 1, wherein the first voltage is a VDD voltage and the second voltage is a VSS voltage.

4. An Schmitt trigger with electrostatic discharge protection comprising:
a plurality of cascaded transistors comprising:
a first transistor having a gate coupled to an input terminal of the Schmitt trigger, and a source coupled to a first voltage; and
a second transistor having a gate coupled to the input terminal of the Schmitt trigger, and a source coupled to a second voltage;
a third transistor having a source coupled to a drain of the first transistor, and a drain coupled to the second voltage through a first poly-silicon resistor; and
a fourth transistor having a source coupled to a drain of the second transistor, and a drain coupled to the first voltage through a second poly-silicon resistor.

5. The Schmitt trigger of claim 4, wherein the first voltage is a VDD voltage and the second voltage is a VSS voltage.

6. The Schmitt trigger of claim 4, wherein the first and third transistors are PMOS transistors while the second and fourth transistors are NMOS transistors.

7. The Schmitt trigger of claim 4 is manufactured by 0.35-μm process or a more advanced process.

8. An Schmitt trigger with electrostatic discharge protection comprising:
a first PMOS transistor having a gate coupled to an input terminal of the Schmitt trigger, a source coupled to a first voltage and a drain;
a second PMOS transistor having a gate coupled to the input terminal of the Schmitt trigger, a source coupled to the drain of the first PMOS transistor and a drain coupled to an output terminal of the Schmitt trigger;
a first NMOS transistor having a gate coupled to the input terminal of the Schmitt trigger, a drain coupled to the drain of the second PMOS transistor and a source;
a second NMOS transistor having a gate coupled to the input terminal of the Schmitt trigger, a drain coupled to the source of the first NMOS transistor and a source coupled to a second voltage;
a third PMOS transistor having a gate coupled to the output terminal of the Schmitt trigger and a source coupled to the drain of the first PMOS transistor;
a third NMOS transistor having a gate coupled to the output terminal of the Schmitt trigger and a source coupled to the source of the first NMOS transistor;
a first impedance unit coupled to a drain of the third PMOS transistor and the second voltage; and
a second impedance unit coupled to a drain of the third NMOS transistor and the first voltage;
wherein the first and the second impedance units are formed with passive devices.

9. The Schmitt trigger of claim 8 is manufactured by 0.35-μm process or a more advanced process.

10. The Schmitt trigger of claim 8, wherein the first voltage is a VDD voltage and the second voltage is a VSS voltage.

11. The Schmitt trigger of claim 8, wherein the first and the second impedance units are respectively composed of a poly-silicon resistor.

12. The Schmitt trigger of claim 8, wherein the first and the second impedance units are respectively composed of a metal resistor.

13. The Schmitt trigger of claim 8, wherein the first and the second impedance units are respectively composed of a diffusion resistor.

14. The Schmitt trigger of claim 8, wherein the first and the second impedance units are respectively composed of a well resistor.
